(19) United States
(12) Patent Application Publication
(10) Pub. No.: US 2012/0243175 A1
(43) Pub. Date: Sep. 27, 2012

(54) COVER, ELECTRONIC DEVICE RACK, AND AIR CONDITIONING SYSTEM

(76) Inventor: Keiichi OKADA, Tokyo (JP)

(21) Appl. No.: 13/426,519

(22) Filed: Mar. 21, 2012

(30) Foreign Application Priority Data
Mar. 25, 2011 (JP) 067424/2011

(51) Int. Cl. H05K 7/20; F28F 13/06

(52) U.S. Cl. 361/690; 165/80.2

(57) ABSTRACT

A cover is provided on one surface of a rack of an electronic device provided with an outlet, and includes a sheet that guides exhaust air exhausted from the outlet in one direction along the one surface. An electronic device rack and an air conditioning system are also disclosed.

This application is based upon and claims the benefit of priority from Japanese patent application No. 2011-067424, filed on Mar. 25, 2011, the disclosure of which is incorporated herein in its entirety by reference.

### BACKGROUND OF THE INVENTION

The present invention relates to a cover, an electronic device rack, and an air conditioning system provided in a computer room where a plurality of racks are installed.

In a computer room, a number of electronic devices such as a server and a router are installed in the same space. These electronic devices generate a great amount of heat. To prevent the heat from causing failures in the electronic devices, an air conditioner is provided in the computer room. A general air conditioner supplies cold air from under the floor of the computer room and exhausts warm air from the ceiling portion of the computer room. Many electronic devices are mounted in 19-inch standard racks. In this case, the cooling air is supplied from the front surface of each rack and exhausted from the rear surface.

In some computer rooms designed before, a rack group including a plurality of lines is provided. Racks facing each other in lines adjacent to each other are arranged such that the front surfaces with inlets face the rear surfaces with outlets. This arrangement prevents formation of a space (hot aisle) where exhaust heat from the electronic devices concentrates or formation of a space (cold aisle) where cold air sent from the air conditioner and to be sucked by the servers concentrates.

However, as the servers and the like have grown more powerful, the amount of heat generated by them has increased. In the above-described arrangement, the air conditioning efficiency consequently lowers because the cold air from under the floor mixes with the warm air exhausted from the electronic devices. This may lead to formation of points where the heat partially concentrates (to be referred to as “hot spots” hereinafter), resulting in failures in the electronic devices. To prevent the decrease in the air conditioning efficiency, Japanese Patent Laid-Open No. 2010-127606 (literature 1) proposes a method of arranging the racks facing each other in lines adjacent to each other such that the front surfaces or rear surfaces face each other. In a method proposed by Japanese Patent Laid-Open No. 2010-032174 (literature 2), a front cover is provided on the front surface of each rack, and a rear cover is provided on the rear surface. An inlet is formed on the lower side of the front cover, and an outlet is formed on the upper side of the rear cover. The inlet is connected to an underfloor air outlet, and the outlet is connected to a ceiling air duct.

However, to apply the arrangement of literature 1 to a computer room, it is necessary to rearrange the racks and stop the servers for this rearrangement, requiring much labor and high cost.

To adopt the method of literature 2 in which the covers are provided with the inlet and outlet, it is necessary to make the cover diameter large to some extent so as to form paths between the racks to do maintenance or ensure an air quantity needed for cooling the electronic devices. To do this, the spaces between the lines of racks need to be wider. This makes the number of rack lines that can be arranged in the computer room smaller than usual and thus leads to a decrease in the number of electronic devices that can be installed in the computer room. In addition, installing the ceiling air ducts is also required. For a computer room having no ceiling air ducts, a construction work is necessary for installing the ceiling air ducts.

### SUMMARY OF THE INVENTION

An exemplary object of the invention is to easily improve the air conditioning efficiency of a computer room.

According to an exemplary aspect of the invention, there is provided a cover provided on one surface of a rack of an electronic device provided with an outlet, and comprising a sheet that guides exhaust air exhausted from the outlet in one direction along the one surface.

According to another exemplary aspect of the invention, there is provided an electronic device rack comprising an outlet provided in one surface, and a cover provided on the one surface to guide exhaust air exhausted from the outlet in one direction along the one surface.

According to still another exemplary aspect of the invention, there is provided an air conditioning system comprising a plurality of racks each of which accommodates an electronic device, and an air conditioning apparatus that supplies cooling air from below to a space between a front surface of one of racks adjacent to each other, which are included in the plurality of racks, and a rear surface of the other rack, each of the plurality of racks comprising an inlet provided in the front surface, an outlet provided in the rear surface, and a cover provided on the rear surface to guide exhaust air exhausted from the outlet in one direction along the rear surface, wherein the plurality of racks are arranged such that the front surface of the one rack of the racks adjacent to each other faces the rear surface of the other rack.

### BRIEF DESCRIPTION OF THE DRAWINGS

FIG. 1 is a perspective view showing the arrangement of a cover according to the first exemplary embodiment of the present invention;

FIG. 2 is a view showing the arrangement of an air conditioning system according to the second exemplary embodiment of the present invention;

FIG. 3 is a perspective view showing the arrangement of a rack shown in FIG. 2;

FIG. 4 is a side view showing the arrangement of the rack shown in FIG. 2; and

FIG. 5 is a side view showing a state in which the rack of the rack shown in FIG. 2 deforms.

### DESCRIPTION OF THE EXEMPLARY EMBODIMENTS

The exemplary embodiments of the present invention will now be described in detail with reference to the accompanying drawings.

### First Exemplary Embodiment

The first exemplary embodiment of the present invention will be described first.

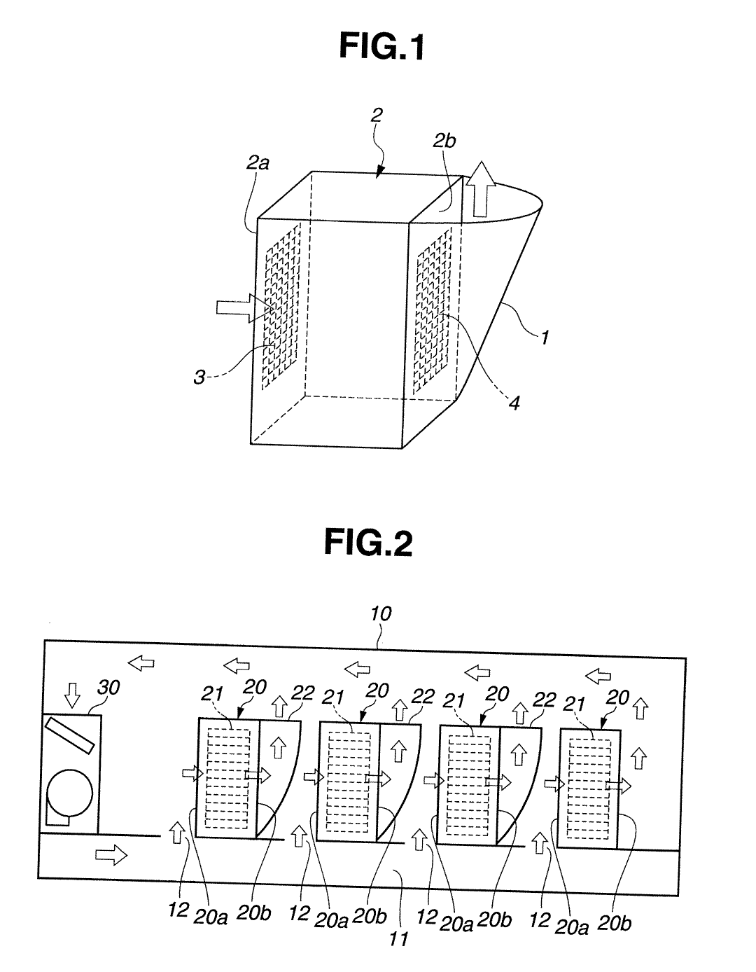

As shown in FIG. 1, a cover according to the first exemplary embodiment is formed from a sheet-shaped member (sheet). The cover 1 is attached to a rear surface (one surface) 2b of a rack 2 that accommodates electronic devices. The rear surface 2b of the rack 2 is provided with an outlet 4. The cover 1 guides exhaust air from the outlet 4 upward (in one direction along the rear surface of the rack).

Providing the cover 1 makes it possible to separate supplied cold air and warm air exhausted from the electronic devices from each other even in a computer room where a front surface 2a of one rack 2 provided with an inlet 3 is arranged so as to face the rear surface 2b of the other rack 2 provided with the outlet 4. For this reason, hot spot formation can be prevented without rearranging the racks 2 that accommodate the electronic devices or stopping the servers for the rearrangement. This allows to easily improve the air conditioning efficiency of the computer room.

Additionally, since the cover 1 is formed from the sheet-shaped member, the air quantity needed for cooling the electronic devices and the paths between the racks 2 can be ensured without widening the spaces between the lines of the racks 2. This makes it possible to improve the air conditioning efficiency without decreasing the number of racks 2 even in a computer room where the racks 2 adjacent to each other are arranged such that their front surfaces and rear surfaces face each other.

### Second Exemplary Embodiment

The second exemplary embodiment of the present invention will be described next.

### <Arrangement of Air Conditioning System>

As shown in FIG. 2, an air conditioning system according to the second exemplary embodiment is applied to a computer room 10 where a number of racks 20 are installed. The racks 20 are arrayed in a plurality of lines. The racks 20 facing each other in lines adjacent to each other are arranged such that an air-sucking front surface 20a of one rack 20 faces an air-exhausting rear surface 20b of the other rack 20.

The computer room 10 has a double floor structure. An underfloor air-conditioning space 11 is provided between the upper floor surface and the lower floor surface. An outlet of an air conditioner (air conditioning apparatus) 30 is connected to the underfloor air-conditioning space 11. The upper floor surface is provided with a plurality of underfloor air outlets 12. The positions of the underfloor air outlets 12 correspond to the positions of the racks 20. The underfloor air outlets 12 are arranged between the racks 20 adjacent to each other, preferably, at positions closer to the racks 20 with the rear surfaces 20b exposed.

The rack 20 is formed from a known rack such as a 19-inch standard rack. A plurality of stages of electronic devices 21 such as a server and a router are mounted in the rack 20. The electronic devices 21 are provided with a plurality of fans. With these fans, cooling air is sucked through an inlet 23 provided in the front surface 20a of the rack 20 and exhausted from an outlet 24 provided in the rear surface 20b.

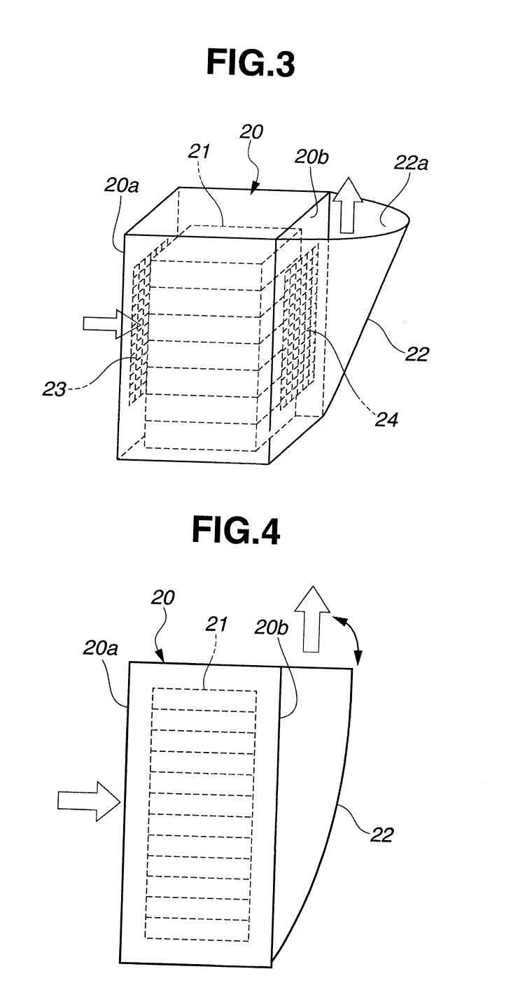

A cover 22 as shown in FIG. 3 is provided on the rear surface 20b of the rack 20. Before attachment to the rack 20, the cover 22 has an almost isosceles trapezoidal planar shape. An edge of the cover 22 corresponding to the short side (lower base) out of the two parallel sides of the isosceles trapezoid is attached to the base portion of the rear surface 20b of the rack 20. Edges of the cover 22 corresponding to the two lateral sides that sandwich the short side are attached to the two side portions of the rear surface 20b of the rack 20. That is, the cover 22 is attached to the periphery of the outlet 24 so as to close the lower, left, and right sides of the outlet 24 and open the upper side of the outlet 24.

When air is exhausted from the outlet 24, the cover 22 swells and forms an almost right-angled triangular shape with an arcuate hypotenuse when viewed from a side, as shown in FIG. 4. When the cover 22 swells, the edge corresponding to the long side (upper base) out of the two parallel sides of the isosceles trapezoid and the upper side portion of the rear surface 20b of the rack 20 form an almost semicircular opening portion 22a.

Various kinds of materials such as a soft cloth and a plastic sheet, which pass little or no air, easily bend, and are not melted by the exhaust heat from the rack 20, are applicable to the cover 22.

As shown in FIG. 2, the air conditioner 30 is formed from a known cooler that cools air taken through an inlet provided on the upper side and exhausts it from an outlet provided on the lower side. As described above, the outlet of the air conditioner 30 is connected to the underfloor air-conditioning space 11.

### <Operation of Air Conditioning System>

The operation of the air conditioning system shown in FIG. 2 will be explained next.

Warm air generated by cooling the electronic devices 21 is exhausted from the outlet 24 provided in the rear surface 20b of each rack 20 toward the cover 22. Since the bottom and lateral sides of the rear surface 20b of the rack 20 are closed by the cover 22, the air rises along the inner surface of the cover 22 and exits from the opening portion 22a toward the ceiling of the computer room 10. The air that has exited from the outlet 24 flows not toward the adjacent rack 20 but upward.

The air exhausted from the cover 22 rises, flows along the ceiling, and finally flows into the inlet of the air conditioner 30. The air that has flowed into the air conditioner 30 through the inlet is cooled by the air conditioner 30 and exhausted from the outlet into the underfloor air-conditioning space 11. The air exhausted into the underfloor air-conditioning space 11 passes through the underfloor air-conditioning space 11 and enters the computer room 10 through the underfloor air outlets 12.

The air that has exited from each underfloor air outlet 12 reaches the space between the racks 20 adjacent to each other. In this space, the front surface 20a of one rack 20 faces the rear surface 20b of the other rack 20. The cover 22 is attached to the rear surface 20b. The space between the one rack 20 and the other rack 20 is partitioned by the cover 22. For this reason, the air that has exited from the underfloor air outlet 12 is taken into the rack 20 whose front surface 20a is directed to the space. At this time, the swelled cover 22 has an almost right-angled triangular shape spreading upward when viewed from the side. Hence, the interval between the cover 22 and the front surface 20a of the one rack 20 facing the cover 22 decreases upward. The air that has exited from the underfloor air outlet 12 is thus more effectively guided into the rack 20 through the inlet 23 of the front surface 20a.

The air introduced into the rack 20 cools the electronic devices 21 and exits from the outlet 24 of the rear surface 20b again.

As described above, according to this exemplary embodiment, attaching the cover 22 to the rack 20 makes it possible to separate cold air supplied from the air conditioner 30 and warm air exhausted from the electronic devices 21 from each other even in the computer room 10 where the front surface 20a of a rack 20 provided with the inlet 23 is arranged so as to face the rear surface 20b of another rack 20 provided with the outlet 24. For this reason, hot spot formation can be prevented without rearranging the racks 20 or stopping the servers for the rearrangement. This allows to easily improve the air conditioning efficiency.

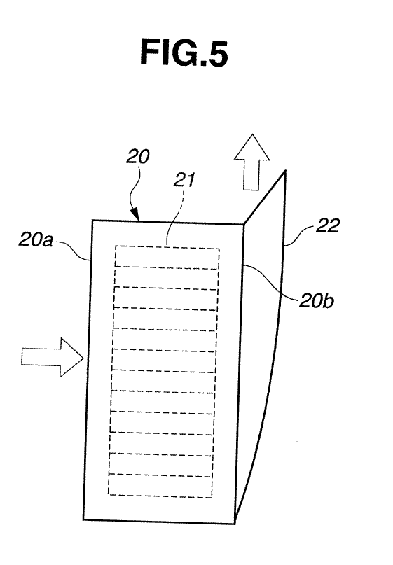

Normally, the cover 22 swells in the direction of the exhaust air flow from the rear surface 20b, as shown in FIG. 4. However, the cover 22 is flexible and can therefore contract in the direction opposite to the direction of the exhaust air flow, as shown in FIG. 5. For this reason, even in a computer room with the conventional arrangement, the air quantity needed for cooling the electronic devices 21 and the paths between the racks 20 can be ensured without widening the spaces between the lines of the racks 20. This makes it possible to improve the air conditioning efficiency without decreasing the number of racks 20.

Note that the cover 22 may be omitted for the rack 20 whose rear surface 20b faces the wall of the computer room 10, as shown in FIG. 2.

In the above-described exemplary embodiment, the cover 22 guides the exhaust air from the outlet 24 upward. However, the exhaust air may be guided in another direction by directing the opening portion 22a, for example, rightward or leftward.

The present invention is applicable to an electronic device that takes air through a fan or the like and cools internal units or a rack that accommodates the electronic device.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

What is claimed is:

1. A cover provided on one surface of a rack of an electronic device provided with an outlet, and comprising a sheet that guides exhaust air exhausted from the outlet in one direction along said one surface.

2. A cover according to claim 1, wherein said sheet is attached to a periphery of the outlet so as to close lower, left, and right sides of the outlet and open an upper side of the outlet.

3. A cover according to claim 1, wherein said sheet attached to the rack has a right-angled triangular shape when viewed from a side.

4. A cover according to claim 1, wherein
said sheet has an isosceles trapezoidal shape before attachment to the rack, and
a short side out of two parallel sides of said sheet and two sides that sandwich the short side are attached to said one surface of the rack.

5. A cover according to claim 1, wherein said sheet is flexile.

6. An electronic device rack comprising:
an outlet provided in one surface; and
a cover provided on said one surface to guide exhaust air exhausted from said outlet in one direction along said one surface.

7. An air conditioning system comprising:
a plurality of racks each of which accommodates an electronic device; and
an air conditioning apparatus that supplies cooling air from below to a space between a front surface of one of racks adjacent to each other, which are included in said plurality of racks, and a rear surface of the other rack,
each of said plurality of racks comprising:
an inlet provided in the front surface;
an outlet provided in the rear surface; and
a cover provided on the rear surface to guide exhaust air exhausted from said outlet in one direction along the rear surface,
wherein said plurality of racks are arranged such that the front surface of said one rack of the racks adjacent to each other faces the rear surface of said other rack.
